(19) United States
(12) Patent Application Publication
(10) Pub. No.: US 2020/0090764 A1
(43) Pub. Date: Mar. 19, 2020

(54) SEMICONDUCTOR MEMORY DEVICE, MEMORY SYSTEM, AND METHOD

(71) Applicant: Toshiba Memory Corporation, Tokyo (JP)

(72) Inventor: Rui ITO, Chigasaki Kanagawa (JP)

(21) Appl. No.: 16/291,473

(22) Filed: Mar. 4, 2019

(30) Foreign Application Priority Data
Sep. 18, 2018 (JP) 2018-173562

(51) Int. Cl. G11C 16/28; G11C 16/10; G11C 16/04; G11C 11/56

(52) U.S. Cl. CPC G11C 16/28; G11C 16/10; G11C 2211/5634; G11C 11/5642; G11C 11/5628; G11C 16/0483

(57) ABSTRACT

A semiconductor memory device includes a plurality of memory cells that include one or more pairs of reference cells that store reference data, and a circuit peripheral thereto. The memory cells are commonly connected to a word line and connected to a plurality of bit lines, respectively. The circuit is configured to apply a read voltage to the word line, cause sense nodes of bit lines connected to the reference memory cells of each pair to be electrically connected to each other, determine whether or not each of the plurality of reference memory cells is ON or OFF based on a voltage at a sense node of each of the plurality of bit lines, and update the read voltage based on the number of reference memory cells determined to be ON and the number thereof determined to be OFF.

### CROSS-REFERENCE TO RELATED APPLICATION

This application is based upon and claims the benefit of priority from Japanese Patent Application No. 2018-173562, filed on Sep. 18, 2018, the entire contents of which are incorporated herein by reference.

### FIELD

Embodiments described herein relate generally to a semiconductor memory device, a memory system, and a method.

### BACKGROUND

A semiconductor memory device having a memory cell transistor (memory cell, for short) is known. A threshold voltage of the memory cell is set to a state among the plurality of states corresponding to data stored therein.

During a reading operation, a determination voltage (also referred to as a read level) is applied to a control gate of the memory cell, and it is determined whether or not a current flows between a source and a drain of the memory cell in a sense amplifier. Then, the state to which the threshold voltage of the memory cell belongs is determined based on a result of determination.

However, an erroneous determination of the state may occur depending on various factors such as manufacturing variations of the memory cells or the sense amplifier, variations of voltage supplied to the sense amplifier, variations of an environmental temperature, and the like.

### DESCRIPTION OF THE DRAWINGS

FIG. 1 is a diagram illustrating a configuration example of a memory system in an embodiment.

FIG. 2 is a diagram illustrating a configuration example of a memory chip in the embodiment.

FIG. 3 is a circuit diagram illustrating a configuration example of a block in a memory cell array in the embodiment.

FIG. 4 is a diagram illustrating an example of possible threshold voltage distributions of memory cells in the embodiment when the memory cell is programmed using a multi-level cell method.

FIG. 5 is a diagram for explaining an example of a configuration for specifying a state of the memory cell in the embodiment.

FIG. 6 is a schematic diagram illustrating an actual change of voltage in a sense amplifier circuit in the embodiment.

FIG. 7 is a diagram illustrating an example of a configuration of a sense amplifier circuit used as a reference sense amplifier circuit in the embodiment.

FIG. 8 is a diagram illustrating a state in which a read level is close to a lobe on a high voltage side in the embodiment.

FIG. 9 is a diagram for explaining a transition of a voltage of the sense amplifier circuit when the read level is close to the lobe on the high voltage side in the embodiment.

FIG. 10 is a diagram for explaining a transition of the voltage of the sense amplifier circuit after calibration in the embodiment.

FIG. 11 is a diagram illustrating an example of an arrangement of a second sense amplifier circuit and memory cells in which reference data are stored, in the embodiment.

FIG. 12 is a flowchart explaining an example of a series of procedures in which a memory chip processes a program command in the embodiment.

FIG. 13 is a flowchart explaining an example of a series of procedures in which the memory chip processes a read command in the embodiment.

FIG. 14 is a flowchart illustrating an example of a procedure of a read operation in the embodiment.

### DETAILED DESCRIPTION

Embodiments provide a semiconductor memory device with improved reading performance against variations in various factors.

In general, according to an embodiment, a semiconductor memory device includes a memory cell array and a circuit peripheral to the memory cell array. The memory cell array includes a plurality of memory cells commonly connected to a word line and connected to a plurality of bit lines, respectively. The plurality of memory cells includes one or more pairs of reference memory cells that store reference data. The circuit is configured to, during a read operation, apply a read voltage to the word line, cause sense nodes of bit lines connected to the reference memory cells of each pair to be electrically connected to each other, determine whether or not each of the plurality of reference memory cells is in an ON state or an OFF state based on a voltage at a sense node of each of the plurality of bit lines, and update the read voltage based on the number of reference memory cells determined to be in the ON state and the number of reference memory cells determined to be in the OFF state.

Hereinafter, a semiconductor memory device according to an embodiment will be described in detail with reference to the accompanying drawings. The invention is not limited by this embodiment.

### Embodiment

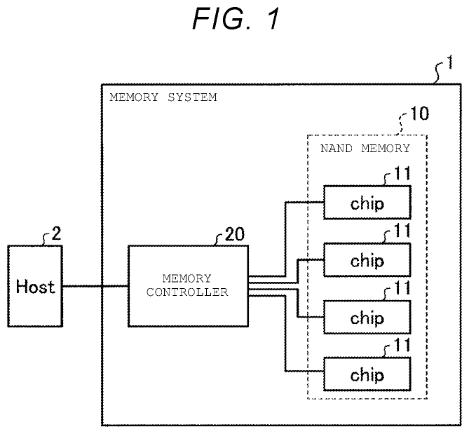

FIG. 1 is a diagram illustrating a configuration example of a memory system in the embodiment. A memory system 1 can be connected to a host (Host) 2 through a predetermined communication interface. The host 2 corresponds to, for example, a personal computer, a mobile information terminal, a server, or the like. The memory system 1 can receive access requests (read request and write request) from the host 2.

The memory system 1 includes a NAND type flash memory (NAND memory) 10 and a memory controller 20.

The memory controller 20 can transmit various commands to the NAND memory 10 autonomously or according to an access request received from the host 2. The memory controller 20 can transmit, for example, a program command for writing data and a read command for reading data, to the NAND memory 10.

The memory controller 20 may include a processor for executing a firmware program. Functions of the memory controller 20 can be achieved by the processor executing the firmware program.

Alternatively, the memory controller 20 may include a hardware circuit such as an application specific integrated circuit (ASIC) or a field programmable gate array (FPGA), and the functions of the memory controller 20 may be implemented by the hardware circuit. Alternatively, the functions of the memory controller 20 may be implemented by a cooperation of the processor and the hardware circuit. That is, the memory controller 20 is a device (circuit) configured with semiconductors.

In addition, the memory controller 20 may be configured as system-on-a-chip (SoC) or may be configured with a plurality of chips.

The NAND memory 10 includes one or more memory chips (Chip) 11. Here, as an example, the NAND memory 10 includes four memory chips 11. The memory chip 11 is an example of a semiconductor memory device.

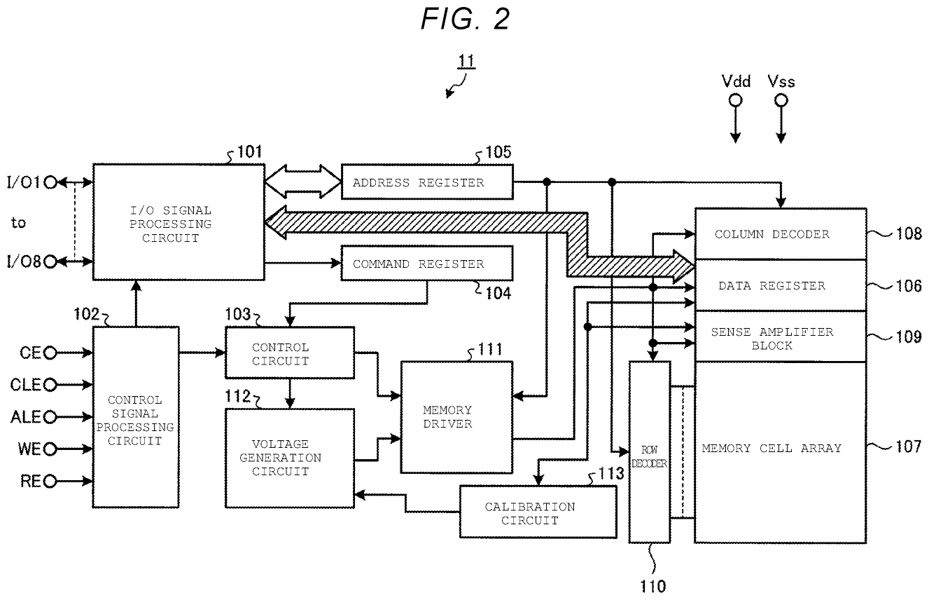

FIG. 2 is a diagram illustrating a configuration example of one memory chip 11 in the embodiment.

The NAND memory 10 includes an I/O signal processing circuit 101, a control signal processing circuit 102, a control circuit 103, a command register 104, an address register 105, a data register 106, a memory cell array 107, a column decoder 108, a sense amplifier block 109, a row decoder 110, a memory driver 111, a voltage generation circuit 112, and a calibration circuit 113.

The row decoder 110 is an example of a first circuit. The calibration circuit 113 is an example of a fifth circuit. The control circuit 103 is an example of a sixth circuit.

The memory cell array 107 includes a plurality of bit lines and a plurality of word lines. The memory cell array 107 includes a plurality of memory cell transistors MT, and each memory cell transistor MT is electrically connected to an intersection of the bit line and the word line.

The memory cell array 107 includes a plurality of blocks each of which includes a plurality of memory cell transistors MT. Data stored in the plurality of memory cell transistors MT configuring one block are erased altogether.

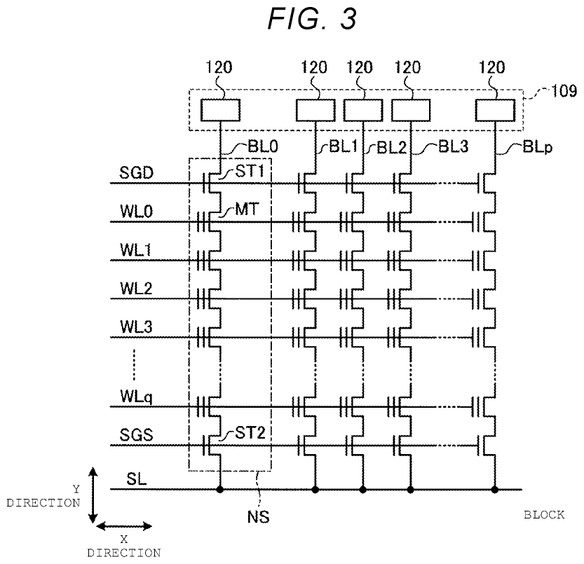

FIG. 3 is a circuit diagram illustrating a configuration example of one block in the memory cell array 107 in the embodiment. As illustrated, each block includes (p+1) NAND strings NS arranged in an order along the X direction (p≥0). In select transistors ST1 in each of the (p+1) NAND strings NS, the drains are connected to the bit lines BL0 to BLp, and the gates are connected in common to a select gate line SGD. In addition, in the select transistors ST2, the sources are connected in common to a source line SL, and the gates are connected in common to a select gate line SGS.

The sense amplifier block 109 includes (p+1) sense amplifier circuits 120 corresponding to (p+1) bit lines BL0 to BLp, respectively. Each sense amplifier circuit 120 is connected to a corresponding bit line BL.

The sense amplifier circuit 120 is an example of a second circuit.

Each memory cell transistor MT may be a metal oxide semiconductor field effect transistor (MOSFET) having a stacked gate structure formed on a semiconductor substrate. The stacked gate structure includes a floating gate formed by interposing a tunnel oxide film on a semiconductor substrate and a control gate electrode formed by interposing an inter-gate insulating film on the floating gate. The threshold voltage changes according to the number of electrons stored in the floating gate. The memory cell transistor MT stores data according to the difference of the threshold voltage. That is, the memory cell transistor MT holds an amount of charges corresponding to the data in the floating gate.

In each NAND string NS, (q+1) memory cell transistors MT are arranged such that their respective current paths are connected in series between the source of the select transistor ST1 and the drain of the select transistor ST2 (q≥0). Then, in an order from the memory cell transistor MT located closest to the drain side, the control gate electrodes are connected to the word lines WL0 to WLq. Therefore, the drain of the memory cell transistor MT connected to the word line WL0 is connected to the source of the select transistor ST1, and the source of the memory cell transistor MT connected to the word line WLq is connected to the drain of the select transistor ST2.

The word lines WL0 to WLq connect the control gate electrodes of the memory cell transistors MT in common between all the NAND strings NS in the block. That is, the control gate electrodes of the memory cell transistors MT in the same row within the block are connected to the same word line WL. A data programming or a data reading can be collectively performed on the (p+1) memory cell transistors MT connected to the same word line WL. When each memory cell MT stores a value of 1 bit, the (p+1) memory cells MT connected to the same word line WL are treated as one page, and thus, the data programming and the data reading are performed for one page at a time.

The operation of performing the data programming on the memory cell array 107 is referred to as a program operation. The operation of performing the data reading from the memory cell array 107 is referred to as a read operation.

That is, the program operation and the read operation can be performed in a unit of word line WL. The read operation may also be referred to as a sense operation.

In the embodiment, each memory cell transistor MT can store a value of plural bits. As an example of a method in which each memory cell transistor MT stores the value of plural bits, a method in which each memory cell transistor MT stores a 2-bit value will be described. Hereinafter, the memory cell transistor MT is simply referred to as a memory cell MT.

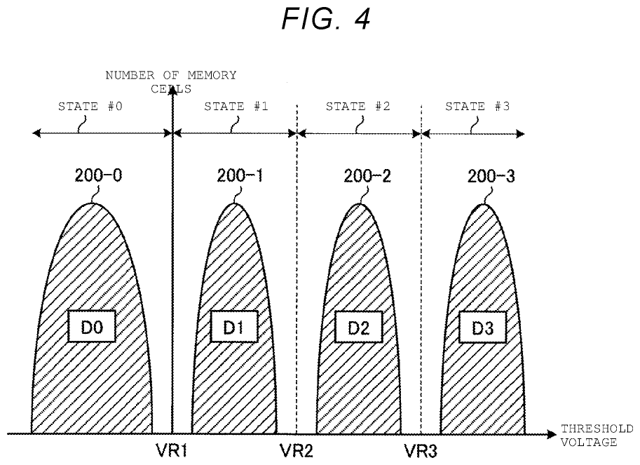

The method in which each memory cell MT stores 2-bit value is known as a multi-level cell (MLC). FIG. 4 is a diagram illustrating an example of a possible threshold voltage distribution of the memory cell in the embodiment when the MLC is adopted. The vertical axis represents the number of memory cells and the horizontal axis represents the threshold voltage.

As illustrated in FIG. 4, the possible range of the threshold voltage is divided into four ranges. The four ranges will be expressed as state #0, state #1, state #2, and state #3 in an order from the lower threshold voltage. The threshold voltage of each memory cell is controlled so as to belong to any one of the state #0, state #1, state #2, and state #3 by the program operation. As a result thereof, when plotting the number of memory cells on the vertical axis and plotting the threshold voltage on the horizontal axis, as illustrated in FIG. 4, the memory cell forms four lobes belonging to each of the different states.

Each state is associated with any one of 2-bit data values “11”, “10”, “00”, and “01” in one-to-one basis in advance. As a result, each memory cell can store 2-bit data.

Data associated with the state #0 is expressed as DO, data associated with the state #1 is expressed as D1, data associated with the state #2 is expressed as D2, and data associated with the state #3 is expressed as D3. That is, each of D0, D1, D2, and D3 is any one of “11”, “10”, “00”, and “01”.

In addition, the lobe corresponding to state #0 is expressed as a lobe 200-0, the lobe corresponding to the state #1 is expressed as a lobe 200-1, the lobe corresponding to the state #2 is expressed as a lobe 200-2, the lobe corresponding to the state #3 is expressed as a lobe 200-3.

At a boundary between adjacent states, a read level is set. A read level set at a boundary between state #0 and state #1 is expressed as a read level VR1. A read level set at a boundary between the state #1 and the state #2 is expressed as a read level VR2. A read level set at a boundary between state #2 and state #3 is expressed as a read level VR3.

In the read operation, the threshold voltage of the memory cell MT to be read is compared with a few read levels, the state to which the threshold voltage of the memory cell MT to be read belongs is specified based on a result of comparison. The number of read levels used for the comparison is not limited to a specific number. For example, three read levels, that is, all the read levels may be used. Alternatively, one or two read levels may be used by devising a method for specifying the state. The specified state is decoded into the corresponding data.

The state #0 corresponds to an erased state. That is, the memory cell MT of state #1, state #2, and state #3 is caused to transit to the state #0 by an erase operation. The erase operation can be performed in units of one block.

Each operation will be described below. Hereinafter, in some cases, the memory cell MT of which the threshold voltage is set to the state # X is simply expressed as a “memory cell MT of state # X”. In addition, in some cases, the state set to the threshold voltage of the memory cell MT may be described as a state of the memory cell MT.

The description will be returned to FIG. 2. The memory chip 11 is connected to the memory controller 20 through a predetermined communication path. The communication path includes a wiring group including an I/O signal line and a control signal line. The I/O signal line is a signal line for transmitting and receiving data, an address, or a command, for example. The address is information indicating a location of an access destination in the memory cell array 107.

The command includes a program command, a read command, an erase command, and the like. The control signal line is a signal line used for transmitting and receiving, for example, a CE (chip enable) signal, an RE (read enable) signal, a WE (write enable) signal, an ALE (address latch enable) signal, a CLE (command latch enable) signal, and the like.

The I/O signal processing circuit 101 includes a buffer circuit for transmitting and receiving the I/O signal to and from the memory controller 20. The I/O signal processing circuit 101 can capture the command, the address, and the data from the memory controller 20 through the I/O signal line. The I/O signal processing circuit 101 stores the command in the command register 104, stores the address in the address register 105, and stores the data in the data register 106.

The control signal processing circuit 102 receives inputs of various control signals and performs distribution of the register of the storage destination of the I/O signal accepted by the I/O signal processing circuit 101 based on the received control signal.

The address to be stored in the address register 105 includes a row address and a column address. The row address is read into the row decoder 110 and the column address is read into the column decoder 108, respectively.

The memory driver 111 is a circuit that supplies various voltages necessary for the access (read operation, program operation, erase operation) to the memory cell array 107, to the row decoder 110, the column decoder 108, and the sense amplifier block 109.

A ground voltage Vss and a power supply voltage Vdd is supplied to the voltage generation circuit 112 from the outside. The voltage generation circuit 112 generates various internal voltages including a read level based on those voltages and commands from the control circuit 103, and supplies the generated various internal voltages to the memory driver 111.

The control circuit 103 is a circuit that makes the state transition based on various control signals received via the control signal processing circuit 102, and controls the overall operations of the memory chip 11 including the operation of the read operation and the operation of the write operation. For example, the control circuit 103 issues commands for controlling various internal voltages, the operation timings, and the like to the memory driver 111, the row decoder 110, the column decoder 108, the sense amplifier block 109, and the voltage generation circuit 112, thereby achieving the access to the memory cell array 107.

For example, in the program operation, the row decoder 110 selects the word line WL based on the row address. The column decoder 108 selects the bit line BL based on the column address. A programming pulse is applied via the row decoder 110 to the control gate of the memory cell MT (expressed as a memory cell MTsel) which is located at an intersection of the word line WL (expressed as a word line WLsel) selected by the row decoder 110 and the bit line BL (expressed as a bit line BLsel) selected by the column decoder 108. By applying the programming pulse, the threshold voltage of the memory cell MTsel is set to a state corresponding to the data stored in the data register 106.

In the read operation, similarly to the program operation, the word line WLsel and the bit line BLsel are selected based on the row address and the column address. The sense amplifier block 109 and the row decoder 110 cooperate to specify the state of the memory cell MTsel located at an intersection of the word line WLsel and the bit line BLsel, and stores data corresponding to the specified state to the data register 106. The data stored in the data register 106 is sent to the I/O signal processing circuit 101 through the data line, and transferred to the memory controller 20 from the I/O signal processing circuit 101.

The state of the memory cell MTsel is specified by, for example, observing the behavior of the memory cell MTsel by applying a read level voltage corresponding to the boundary between the states, to the control gate of the memory cell MTsel.

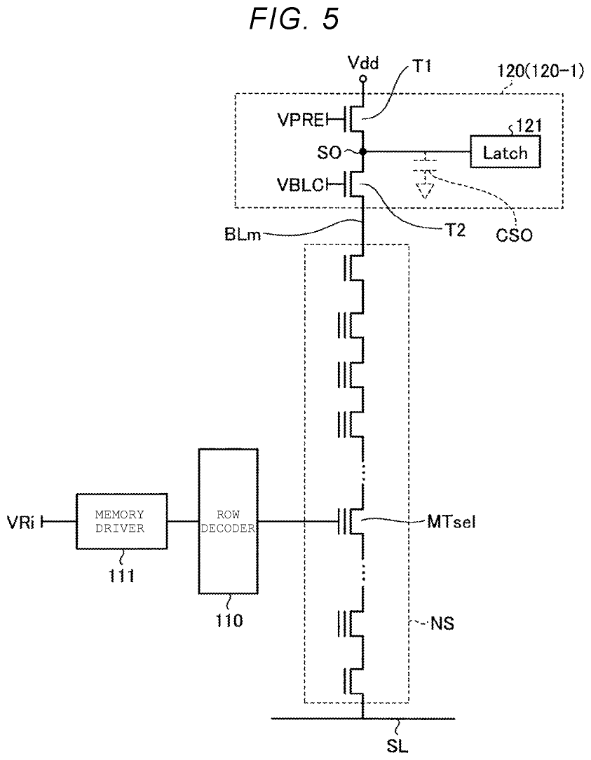

FIG. 5 is a diagram for explaining an example of a configuration of the memory cell MTsel in the embodiment for specifying the state of the memory cell MTsel. Here, as an example, with regard to a memory cell MTsel connected to a bit line BLm (m is an integer from 0 to p), a configuration for determining whether the threshold voltage is set to a state higher than a read level VRi (i is 1, 2, or 3) or the threshold voltage is set to a state lower than the read level VRi, will be described.

The sense amplifier circuit 120 includes transistors T1 and T2 and a latch 121. In the transistor T2, any one of a source and a drain is connected to the bit line BLm, and the other is connected to a node SO (sense node). In the transistor T1, any one of a source and a drain is connected to the node SO, and the other is connected to a power voltage Vdd. The latch 121 is connected to the node SO.

When specifying the state of the memory cell MTsel, the sense amplifier circuit 120 applies a voltage VBLC to the gate of transistor T2 and a voltage VPRE to the gate of transistor T1. Here, VPRE≥VBLC. The voltage of the bit line BLm is clamped to a predetermined voltage (a pre-charge voltage) by the transistor T2, and thus, the bit line BLm is in a pre-charged state.

The row decoder 110 makes each memory cell MT enter an ON state regardless of the threshold voltage by applying the voltage VREAD to the control gate of all the memory cells MT connected to the bit line BLm except the memory cell MTsel (not illustrated). Then, the row decoder 110 applies the read level VRi to the gate of the memory cell MTsel. The value of the voltage VREAD is larger than any read level VRi.

When the threshold voltage of memory cell MTsel is lower than the read level VRi, and accordingly the memory cell MTsel enters an ON state, the NAND string NS is in a conduction state, and thus, the cell current flows in the NAND string NS. Therefore, ideally, the voltage VSO on the node SO drops sharply.

In contrast, when the threshold voltage of the memory cell MTsel is higher than the read level VRi, and accordingly the memory cell MTsel is in the OFF state, the NAND string NS is in a non-conduction state, and thus, the cell current does not flow in the NAND string NS. Therefore, the voltage VSO is ideally maintained at the pre-charge voltage, and accordingly, the voltage VSO on the node SO is maintained at a high value.

The latch 121 compares the voltage VSO and the predetermined voltage VLATCH at a predetermined timing. When the voltage VSO is higher than the voltage VLATCH, the latch 121 regards that no cell current flows in the NAND string NS, and determines that the memory cell MTsel is in the OFF state. The latch 121 acquires a value indicating that the memory cell MTsel is in the OFF state.

On the other hand, when the voltage VSO is lower than the voltage VLATCH, the latch 121 regards that the cell current flows in the NAND string NS, and determines that the memory cell MTsel is in the ON state. The latch 121 acquires a value indicating that the memory cell MTsel is in the ON state.

As described above, the latch 121 determines whether the memory cell MTsel is in the ON state or in the OFF state based on the change of the voltage VSO.

The fact that the memory cell MTsel is in the ON state means that the memory cell MTsel is in a state of being in the low voltage side compared to the read level VRi. The fact that the memory cell MTsel is in the OFF state means that the memory cell MTsel is in the state of being in the high voltage side as compared with the read level VRi.

The determination described above is performed one or more times while changing the read level. The value acquired by the latch 121 through each determination that is performed is stored in a predetermined register (not illustrated) in the sense amplifier circuit 120. The sense amplifier circuit 120 determines the data stored in the memory cell MTsel based on the result for determination for each read level. Then, the sense amplifier circuit 120 stores the determined data in the data register 106.

In the above description, the case where the voltage VSO changes ideally has been described. In reality, even though the memory cell MTsel is in the OFF state, the voltage VSO can be decreased as time elapses. In addition, even when the memory cell MTsel is in the ON state, the voltage VSO may not decrease sharply.

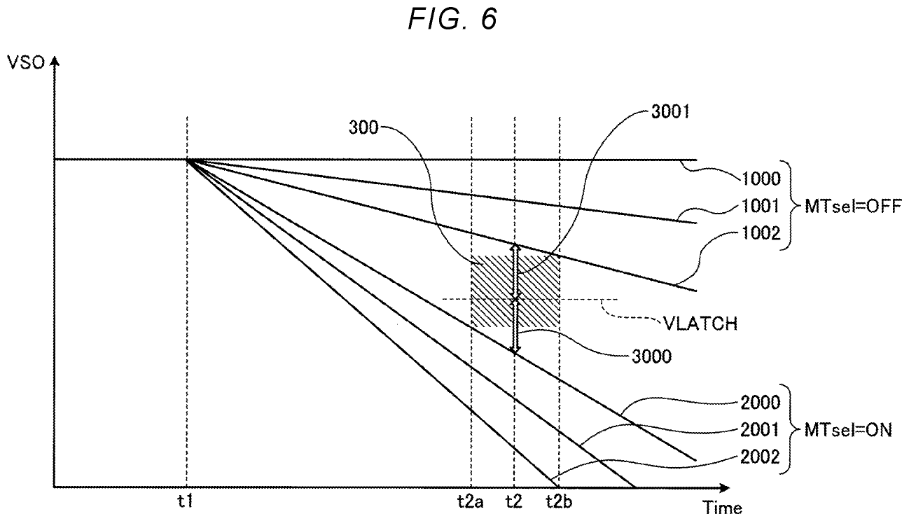

FIG. 6 is a schematic diagram illustrating the actual change of the voltage VSO in the sense amplifier circuit 120 in the embodiment. In FIG. 6, the vertical axis represents the value of the voltage VSO, and the horizontal axis represents the time. A time point t1 indicates a timing of starting the operation of the sense amplifier circuit 120, and time point t2 indicates the timing at which the latch 121 acquires the value.

For example, when the read level VRi is VR2 and the memory cell MTsel is in the state #2, the memory cell MTsel is in the OFF state. However, even when the memory cell MT is in the OFF state, a leakage current flows the memory cell MT. The current value of the leakage current increases as the difference between the threshold voltage and the read level decreases.

On the other hand, as described with reference to FIG. 4, the distribution of the threshold voltage for each state has a lobe shape. That is, among a plurality of memory cells MT in the same state, the threshold voltage varies. For example, even among the plurality of memory cells MT in the state #2, in the case of the memory cell MT with the threshold voltage close to the read level VR2, a current leakage amount becomes larger than that of the memory cell MT with the threshold voltage far from the read level VR2.

Therefore, as illustrated in FIG. 6, when the memory cell MTsel is in the OFF state, the drop rate of the voltage VSO varies as illustrated by straight lines 1000, 1001, and 1002, for example, according to the magnitude of the difference between the threshold voltage and the read level VRi of the memory cell MTsel. When the difference between the threshold voltage and the read level VRi of the memory cell MTsel is sufficiently large, the voltage VSO scarcely drops at all even though the time elapses (for example, the straight line 1000). On the other hand, when the difference between the threshold voltage and the read level VRi of the memory cell MTsel is small, the voltage VSO drops sharply as the time elapses (for example, the straight line 1002).

In addition, for example, when the read level VRi is VR2 and the memory cell MTsel is in the state #1, the memory cell MTsel is in the ON state. However, when the transistor is in the ON state, a current having the amount corresponding to the voltage difference between the gate and the source flows. The above description also applies to the memory cell MT.

Therefore, as illustrated in FIG. 6, when the memory cell MTsel is in the ON state, the drop rate of the voltage VSO varies as illustrated by the straight lines 2000, 2001, and 2002, for example, according to the magnitude of the difference between the threshold voltage and the read level VRi of the memory cell MTsel. When the difference between the threshold voltage and the read level VRi of the memory cell MTsel is small, since the amount of cell current is small, the drop rate of the voltage VSO according to the elapse of time decreases (for example, the straight line 2000). When the difference between the threshold voltage and the read level VRi of the memory cell MTsel is large, since a large amount of cell current flows, for example, the voltage VSO rapidly drops as the time elapses as illustrated by the straight line 2002.

As described above, the drop rate of the voltage VSO varies according to the variation of the threshold voltage. The drop rate of the voltage VSO is, for example when the voltage VSO drops, the absolute value of the slope of the voltage VSO.

Reasons for the variation of the drop rate of the voltage VSO is not limited to the variation of the threshold voltage difference. For example, a parasitic capacity CSO of the node VSO varies due to manufacturing variations, and thus, the drop rate of the voltage VSO can change in each sense amplifier circuit 120. In addition, the drop rate of the voltage VSO can also change depending on the ambient temperature of the memory chip 11. In addition, the behavior of the voltage VSO can also change by the variation of the power voltage Vdd.

In addition, the time from the time point t1 to the time t2 is determined by the cycle (frequency) of a clock (not illustrated) supplied to the memory chip 11. Due to the variation of the clock, the timing at which the latch 121 acquires the value may be changed to a time point t2a or a time point t2b.

In the case where a transition of the voltage VSO when the memory cell MTsel is in the OFF state varies in a range of straight lines 1000 to 1002, and a transition of the voltage VSO when the memory cell MTsel is in the ON state varies in a range of the straight lines 2000 to 2002, and a timing at which the latch 121 acquires a value varies in a range from the time point t2a to the time point t2b, the voltage VLATCH needs to be in a range indicated by a numeral code 300 in order for the latch 121 to correctly determine the state of the memory cell MTsel.

A range 3000 from the voltage VLATCH to the upper limit of the range where the voltage VSO transition is distributed when the memory cell MTsel is in the ON state, and a range 3001 from the voltage VLATCH to the lower limit of the range where the transition of the voltage VSO is distributed when the memory cell MTsel is in the OFF state are margins for the latch 121 to correctly determine the state of the memory cell MTsel at the timing of the time point t2.

In the embodiment, the determination voltage VRi is adjusted such that the range 3000 and the range 3001 becomes equal as possible. In this way, for example, even when the timing at which the latch 121 acquires the value is changed to the time point t2a or the time point t2b, the determination voltage VRi is adjusted such that the voltage VLATCH falls within the range 300.

As a configuration for achieving the above characteristics, the memory chip 11 includes a sense amplifier circuit 120 (120-2) used as a reference sense amplifier circuit and a calibration circuit 113.

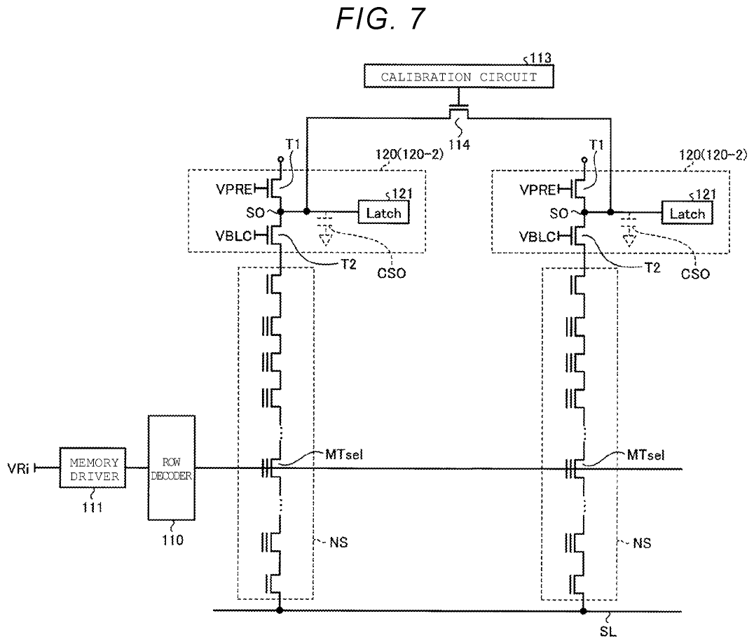

FIG. 7 is a diagram illustrating an example of a configuration of a sense amplifier circuit 120 used as the reference sense amplifier circuit in the embodiment. Hereinafter, the sense amplifier circuit 120 described with reference to FIG. 5 will be referred to as a first sense amplifier circuit 120-1. The sense amplifier circuit 120 used as the reference sense amplifier circuit, illustrated in FIG. 7, is referred to as a second sense amplifier circuit 120-2. That is, the (p+1) sense amplifier circuits 120 include the first sense amplifier circuit 120-1 and the second sense amplifier circuit 120-2.

The two second sense amplifier circuits 120-2 configure one unit (one pair).

One of the pair of second sense amplifier circuits 120-2 is an example of a third circuit. The other of the pair of second sense amplifier circuits 120-2 is an example of a fourth circuit.

Each of the pair of second sense amplifier circuits 120-2 has the same configuration as the first sense amplifier circuit 120-1 except that the nodes SO are connected to each other via the switch element 114.

The reference data generated by the calibration circuit 113 is stored in the NAND strings NS connected to each of the pair of second sense amplifier circuits 120-2.

The data corresponding to one state of two mutually adjacent states is stored in the memory cell MT connected to one of the pair of second sense amplifier circuits 120-2. In addition, the data corresponding to the other state of the two mutually adjacent states is stored in the memory cell MT of the NAND string NS connected to the other one of the pair of second sense amplifier circuits 120-2.

That is, the Di-1 is stored in the memory cell MT connected to one of the pair of second sense amplifier circuits 120-2, and the Di is stored in the memory cell MT connected to the other one of the pair of second sense amplifier circuits 120-2.

At a time of the program operation, a switch element 114 is put in the OFF state by the calibration circuit 113, and the reference data is individually written into each of the pair of second sense amplifier circuits 120-2.

At the time of a read operation, each of the pair of second sense amplifier circuits 120-2 performs the same processing as the first sense amplifier circuit 120-1 while the switch element 114 is in the ON state. That is, each of the second sense amplifier circuits 120-2 performs the determination according to the change in the voltage VSO.

A plurality of pairs of the above-described second sense amplifier circuits 120-2 are provided in the block. The calibration circuit 113 acquires the result of determination by the latch 121 of each second sense amplifier circuit 120-2. The calibration circuit 113 performs the calibration of the read level VRi based on the acquired result of determination.

For example, the case where the reference data are D1 and D2 and the read level is VR2 may be considered. In that case, the memory cell MTsel connected to one of the pair of second sense amplifier circuits 120-2 is in the state #1, and thus, the state of the memory cell MTsel enters an ON state. On the other hand, the memory cell MTsel connected to the other one of the pair of second sense amplifier circuits 120-2 is in the state #2, and thus, the state of the memory cell MTsel is OFF state. Because the switch element 114 is in the ON state, the nodes SO of the pair of second sense amplifier circuits 120-2 are electrically connected to each other to be in the conduction state. As a result, the voltage VSO of each of the pair of second sense amplifier circuits 120-2 is approximately the mean of the voltage value when the memory cell MTsel is in the ON state and the voltage value when the memory cell MTsel is in the OFF state.

That is, the change in the voltage VSO of each of the pair of second sense amplifier circuits 120-2 is a transition intermediate between the transition of the voltage VSO when the memory cell MTsel is in the ON state and the transition of the voltage VSO when the memory cell MTsel is in the OFF state.

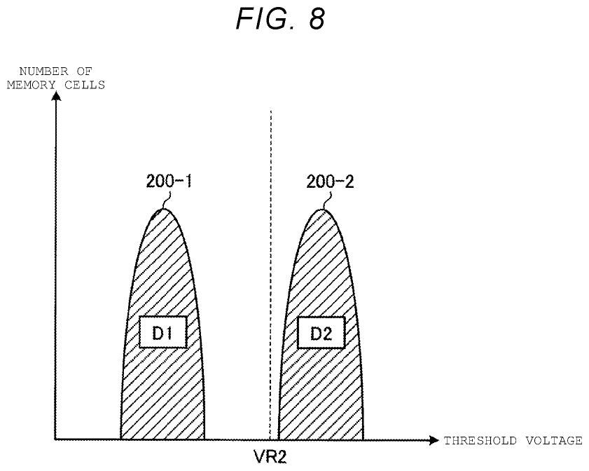

Here, for example, the difference between the threshold voltage of the memory cell MT belonging to lobe 200-2 and the read level VR2 is small, and the difference between the threshold voltage of the memory cell MT belonging to lobe 200-1 and the read level VR2 is large, when the read level VR2 is closer to the lobe 200-2 than to the lobe 200-1 as illustrated in FIG. 8, compared to the case where the read level VR2 is set midway between the lobe 200-1 and the lobe 200-2. Therefore, the current value of the cell current of the memory cell MTsel in the state #1 and of the memory cell MTsel in the state #2 increases, and thus, the drop rate of the voltage VSO of each sense amplifier circuit 120 increases. As a result, the range in which the voltage VSO transition of each second sense amplifier circuit 120-2 is distributed is shifted to the low voltage side.

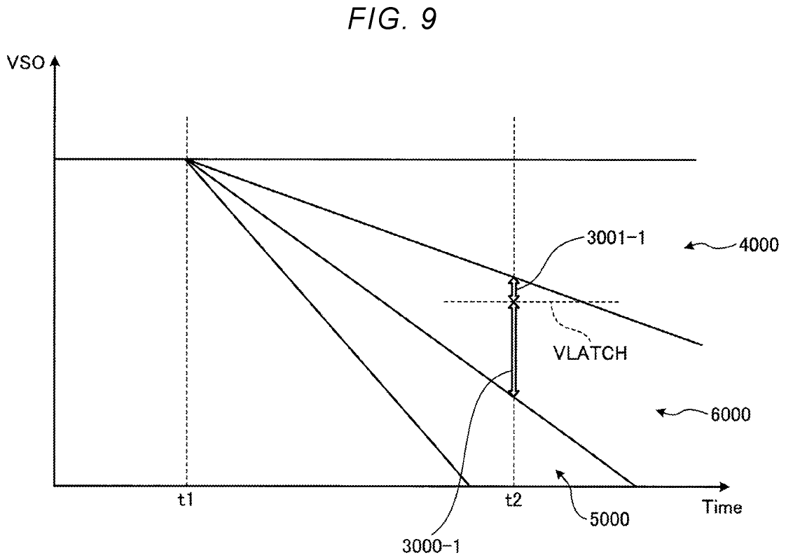

FIG. 9 is a diagram for explaining a transition of the voltage VSO of the sense amplifier circuit 120 in the embodiment when the read level VR2 is closer to the lobe 200-2 than to the lobe 200-1.

A region 6000 indicates the range in which the transition of the voltage VSO of each second sense amplifier circuit 120-2 is distributed. According to the example of FIG. 9, the range (the region 6000) in which the transition of the voltage VSO of each second sense amplifier circuit 120-2 is distributed is relatively close to the low voltage side. A region 4000 that is more toward the higher voltage side than the region 6000 indicates the range in which the transition of the voltage VSO of the first sense amplifier circuit 120-1 is distributed when the memory cell MTsel is in the state #1. A region 5000 that is more toward the lower voltage side than the region 6000 indicates the range in which the transition of the voltage VSO of the first sense amplifier circuit 120-1 is distributed when the memory cell MTsel is in the state #2.

If the range in which the transition of the voltage VSO of each second sense amplifier circuit 120-2 is distributed is close to the low voltage side, since the margin 3000-1 on the low voltage side of the voltage VLATCH and the margin 3001-1 on the high voltage side of the voltage VLATCH are not equal to each other, there is a high possibility that an erroneous determination may occur due to various variations.

In the state where the range (the region 6000) in which the transition of the voltage VSO of each second sense amplifier circuit 120-2 is distributed is close to the low voltage side as described above, the number of second sense amplifier circuits 120-2 that output a value indicating the ON state exceeds the number of second sense amplifier circuits 120-2 that output a value indicating the OFF state.

The calibration circuit 113 counts the number of second sense amplifier circuits 120-2 (that is, the number of results of determination indicating the ON state) that output the value indicating the ON state, and the number of second sense amplifier circuits 120-2 that output the value indicating the OFF state (that is, the number of results of determination indicating the OFF state) based on the result of determination acquired from each second sense amplifier circuit 120-2.

If the number of second sense amplifier circuits 120-2 that output the value indicating the ON state is larger than the number of second sense amplifier circuits 120-2 that output the value indicating the OFF state, the calibration circuit 113 changes the read level VR2 to a value smaller than the current set value.

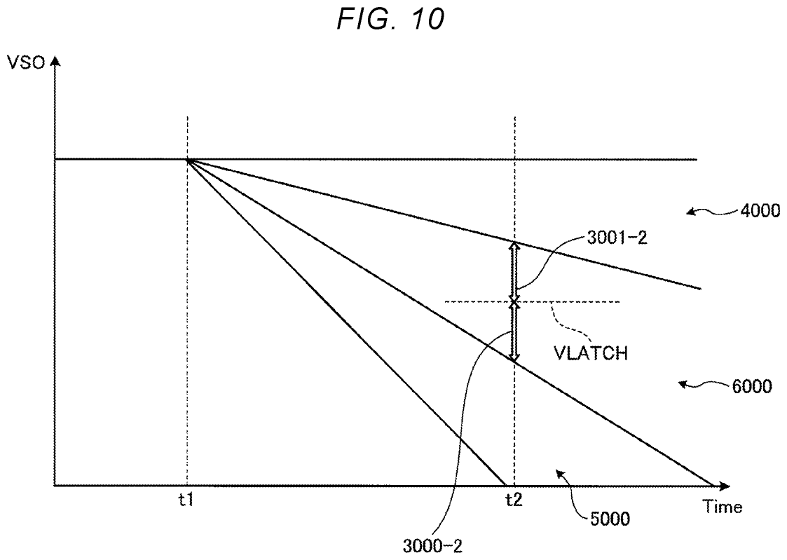

In this way, for example as illustrated in FIG. 10, the range (the region 6000) in which the transition of the voltage VSO of each second sense amplifier circuit 120-2 is distributed can be shifted to a higher voltage side than the example illustrated in FIG. 9. As a result, the margin 3000-2 on the low voltage side of the voltage VLATCH and the margin 3001-2 on the high voltage side of the voltage VLATCH can be made approximately equal to each other, and thus, it is possible to reduce the possibility of occurrence of the erroneous determination due to various variations. That is, the resistance to adverse effects of various variations is improved.

Conversely, when the read level VR2 is closer to the lobe 200-1 than to the lobe 200-2, the values of the current of the memory cell MTsel in the state #1 and of the memory cell MTsel in the state #2 decrease. As a result, the drop rate of the voltage VSO of each second sense amplifier circuit 120-2 decreases. Therefore, the range in which the transition of the voltage VSO of each second sense amplifier circuit 120-2 is distributed is shifted to the high voltage side.

If the range in which the transition of the voltage VSO of each second sense amplifier circuit 120-2 is distributed is close to the high voltage side, since a margin on the low voltage side of the voltage VLATCH becomes smaller than a margin on the high voltage side of the voltage VLATCH, there is a high possibility that an erroneous determination may occur due to variations in various factors.

If the number of second sense amplifier circuits 120-2 that output the value indicating the ON state is smaller than the number of second sense amplifier circuits 120-2 that output the value indicating the OFF state, the calibration circuit 113 changes the read level VR2 to a value larger than the current set value. In this way, the range in which the transition of the voltage VSO of each second sense amplifier circuit 120-2 is distributed can be shifted to the low voltage side.

As a result, the margin on the high voltage side of the voltage VLATCH and the margin on the low voltage side of the voltage VLATCH can be made approximately equal, and thus, it is possible to reduce the possibility of occurrence of the erroneous determination due to various variations. That is, the resistance to ill effects of various variations is improved.

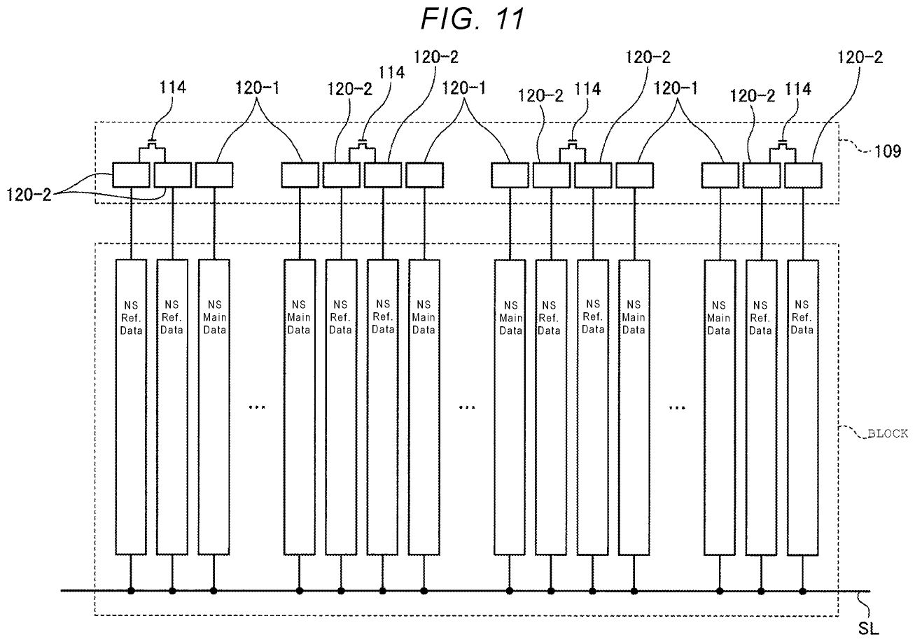

FIG. 11 is a diagram illustrating an example of an arrangement of the second sense amplifier circuits 120-2 and the memory cells MT (NAND string NS) in which the reference data are stored, in the embodiment.

In this example, a pair of second sense amplifier circuits 120-2 are arranged to be dispersed as uniformly as possible in one block. The reference data (Ref. Data) is stored in each memory cell MT configuring the NAND string NS connected to the second sense amplifier circuit 120-2. The main data is stored in each memory cell MT configuring the NAND string NS connected to the first sense amplifier circuit 120-1.

The main data means the target data for programing, which is received from the memory controller 20. The main data includes, for example, the data sent from the host 2, numeral codes for correction of errors generated from the data sent from the host 2, and various management information of the memory system 1.

The method of arrangement of the second sense amplifier circuit 120-2 is not limited to the example described above. Two second sense amplifier circuits 120-2 configuring a pair may be adjacent to each other or not adjacent to each other as illustrated in FIG. 11.

In addition, the number of pairs of the second sense amplifier circuits 120-2 in the block may be one or may be plural. As the number of pairs of the second sense amplifier circuits 120-2 increases, the margin on the high voltage side of the voltage VLATCH and the margin on the low voltage side of the voltage VLATCH can be made more equal.

Also, a pair of second sense amplifier circuits 120-2 may be provided for each read level. For example, one or more pairs of second sense amplifier circuits 120-2 corresponding to the read level VR1, one or more pairs of second sense amplifier circuits 120-2 corresponding to the read level VR2, and one or more pairs of second sense amplifier circuits 120-2 corresponding to the read level VR3 are provided in one block. In the embodiment, a plurality of pairs of second sense amplifier circuits 120-2 in each read level are provided.

D (i-1) is stored as the reference data in the memory cell MT connected to one of the pair of second sense amplifier circuits 120-2 corresponding to the read level VRi. Di is stored as the reference data in the memory cell MT connected to one of the pair of second sense amplifier circuits 120-2 corresponding to the read level VRi.

Next, the operation of the memory chip 11 in the embodiment will be explained.

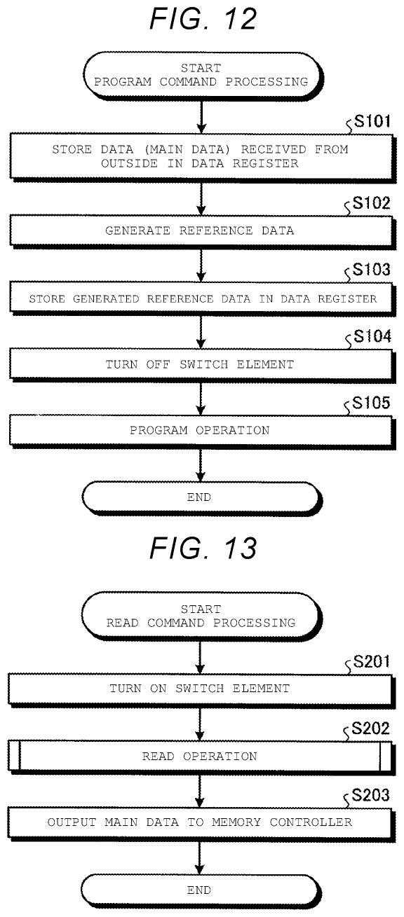

FIG. 12 is a flowchart explaining an example of a series of procedures in which a memory chip 11 in the embodiment processes a program command.

At the time of program command processing, first, an I/O signal processing circuit 101 stores the data (main data) received from the memory controller 20 in the data register 106 (S101). The calibration circuit 113 generates the reference data (S102), and stores the generated reference data in the data register 106 (S103). The calibration circuit 113 turns OFF the switch element 114 (S104).

The control circuit 103 performs a program operation by controlling various configuration elements (S105). In this way, the main data is stored in the memory cell MTsel connected to the first sense amplifier circuit 120-1 and the reference data is stored in the memory cell MTsel connected to the second sense amplifier circuit 120-2.

The program operation may include a read operation to verify whether the threshold voltage of each memory cell MTsel is set to the state corresponding to the data. Such a read operation may also be referred to as a verify read operation.

The program command processing is completed by the program operation.

FIG. 13 is a flowchart explaining an example of a series of procedures in which the memory chip 11 in the embodiment processes a read command.

At the time of read command processing, first, the calibration circuit 113 turns ON the switch element 114 (S201). The control circuit 103 executes the read operation by controlling various constituent elements (S202).

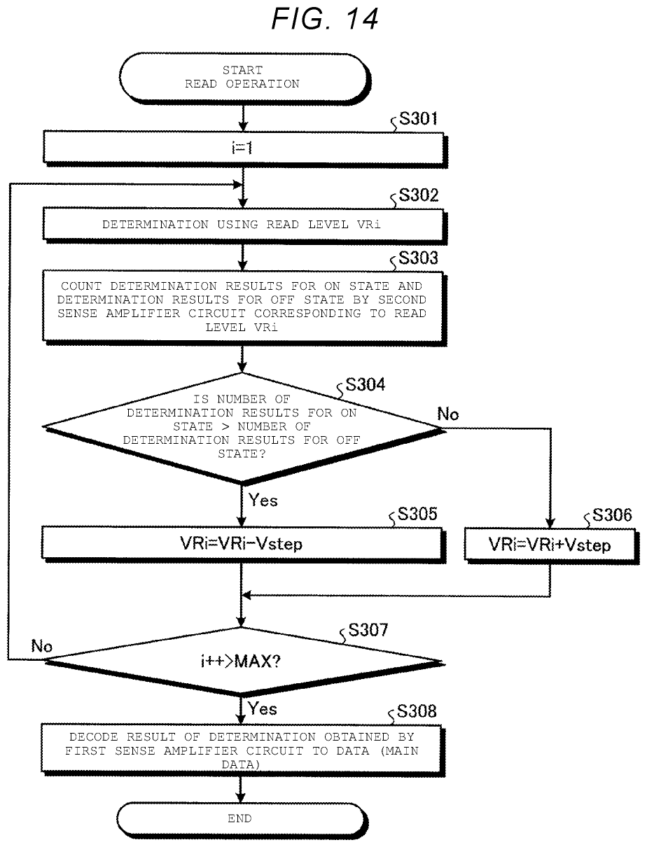

FIG. 14 is a flowchart illustrating an example of a procedure of the read operation in the embodiment.

In the read operation, first, the control circuit 103 sets a loop counter i to 1 (S301). The loop counter i can take values from 1 to the number of read levels. For example in the case of the MLC, the loop counter i can take values from 1 to 3.

After S301, the control circuit 103 performs the determination using the read level VRi (S302). That is, in S302, the read level VRi is applied to the selected word line WLsel, and in each sense amplifier circuit 120, the latch 121 determines whether the memory cell MTsel is in the ON state or in the OFF state based on the change of the voltage VSO at the node SO.

Subsequently, the calibration circuit 113 counts the results of determination indicating the ON state and the results of determination indicating the OFF state made by the second sense amplifier circuits 120-2 corresponding to the read level VRi (S303).

The calibration circuit 113 compares the number of results of determination indicating the ON state with the number of results of determination indicating the OFF state obtained by the processing in S303, and then, determines whether the number of results of determination indicating the ON state is larger than the number of results of determination indicating the OFF state (S304).

If it is determined that the number of results of determination indicating the ON state is larger than the number of results of determination indicating the OFF state (YES in S304), the calibration circuit 113 updates the set value of the read level VRi to a value that is smaller than the current set value as much as a predetermined increment Vstep (S305).

If it is determined that the number of results of determination indicating the ON state is not larger than the number of results of determination indicating the OFF state (NO in S304), the calibration circuit 113 updates the set value of the read level VRi to a value that is larger than the current set value by as much as the predetermined step width Vstep (S306).

The set value of the read level VRi is stored in a predetermined storage region (for example, a register in the voltage generation circuit 112). In the processing in S305 and S306, the calibration circuit 113 updates the set value stored in the storage region. The updated set value is used when the read level VRi is applied next time.

After the processing in S305 or S306, the control circuit 103 increases the value of i by an increment of 1, and determines whether the value of i after the increment exceeds the maximum value of the possible range of i (S307).

If it is determined that the value of i after the increment does not exceed the maximum value of the possible range of i (NO in S307), the control proceeds to S302.

If it is determined that the value of i after the increment exceeds the maximum value of the possible range of i (YES in S307), the sense amplifier block 109 decodes the result of determination obtained by the first sense amplifier circuit 120-1 to the data (main data) (S308). The data (main data) obtained by the decoding is stored in the data register 106.

In this way, the read operation ends.

When the MLC is adopted, three read levels VR1 to VR3 are used. In the description of FIG. 14, the read level VR1, the read level VR2, and read level VR3 are used in this order. The order of using each read level is not limited to this. For example, the order of using each read level may be in an order of the read level VR2, the read level VR1, and the read level VR3.

In addition, in the description above, when the number of results of determination indicating the ON state is equal to the number of results of determination indicating the OFF state, it is determined as NO in the determination processing in S304. The determination processing when the number of results of determination indicating the ON state is equal to the number of results of determination indicating the OFF state is not limited thereto. When the number of results of determination indicating the ON state is equal to the number of results of determination indicating the OFF state, it may be determined as YES in the determination processing in S304.

The description will be returned to FIG. 13. When the read operation ends, the I/O signal processing circuit 101 outputs the main data read from the memory cell array 107 and stored in the data register 106 to the memory controller 20 (S203). Then, the read command processing ends.

As described above, the calibration of each read level is performed by one read operation. As the read operation is repeatedly performed, each read level can be set to an appropriate value.

In the above description, the set value of read level is changed by Vstep at each calibration. The amount of change in one calibration is not limited to thereto.

For example, the calibration circuit 113 may change the amount of change according to the ratio between the number of results of determination indicating the ON state and the number of results of determination indicating the OFF state counted by the processing in S303. For example, the amount of change may be increased in accordance with increase of deviation of the ratio between the number of results of determination indicating the ON state and the number of results of determination indicating the OFF state from 1:1.

In addition to the above description, an example in the case where the MLC is adopted is described. The technology in the embodiment may be applied without depending on the number of bits of the data stored in the memory cell MT. For example, the technology in the embodiment may be applied to a memory chip adopting a method called a single-level cell (SLC) in which one bit of data is stored in the memory cell MT. In addition, the technology in the embodiment may also be applied to a memory chip adopting a method called a triple-level cell (TLC) in which 3-bit data is stored in the memory cell MT, or to a memory chip adopting a method called a quad-level cell (QLC) in which 4-bit data is stored in the memory cell MT.

In the above description, the memory cells MT are two-dimensionally arranged. The memory cell array 107 may have a configuration in which the memory cells MT are three-dimensionally arranged. In this case, for example, a stacked body in which a conductive film and an insulating film are alternately stacked is penetrated by a columnar semiconductor pillar, and the memory cell MT is provided at a portion where the conductive film and the semiconductor pillar intersect each other.

As described above, according to the embodiment, a plurality of sense amplifier circuits 120 that determine whether the memory cell MTsel is in the ON state or in the OFF state according to the change in the voltage VSO at the node SO include at least one pair of second sense amplifier circuits 120-2. During the read operation, that is, when applying the read level to the word line WLsel using the row decoder 110, the calibration circuit 113 electrically connects the node VO of each of the pair of second sense amplifier circuits 120-2 to each other into a conduction state. Then, the calibration circuit 113 performs the calibration of the read level based on the result of determination whether the corresponding memory cell MTsel is in the ON state or in the OFF state performed by each of the pair of second sense amplifier circuits 120-2. That is, the calibration circuit 113 updates the read level.

With this configuration, as described using FIG. 10, the margin 3000-2 on the low voltage side of the voltage VLATCH and the margin 3001-2 on the high voltage side of the voltage VLATCH can be made approximately equal. As a result, even when the drop rate of the voltage VSO and the timing at which the latch 121 acquire the values vary due to various variations, it is possible to make the voltage VLATCH hard to deviate from the range (range 300 in FIG. 6, for example) in which the latch 121 can correctly determine the state of the memory cell MTsel.

That is, the resistance to various variations is improved.

The memory cell MT connected to one of the pair of second sense amplifier circuits 120-2 is set to a state # (i-1) among the two states (a state # (i-1) and a state #0 i) adjacent to each other. The memory cell MT connected to the other one of the pair of second sense amplifier circuits 120-2 is set to the state # i among the state # (i-1) and the state # i. The calibration circuit 113 updates the read level VRi corresponding to the boundary between the state # (i-1) and the state # i based on the result of determination performed by the pair of second sense amplifier circuits 120-2.

In addition, the nodes SO of each of the pair of second sense amplifier circuits 120-2 are connected to each other via the switch element 114. The calibration circuit 113 electrically causes the nodes SO of the pair of second sense amplifier circuits 120-2 to be in the conduction state by turning ON the switch element 114.

With this configuration, the calibration circuit 113 can cause the nodes SO of the pair of second sense amplifier circuits 120-2 to be in the electrical conduction state during the read operation, and can cause the nodes SO of the pair of second sense amplifier circuits 120-2 to be in the electrical non-conduction state during other operations including the program operation.

The calibration circuit 113 turns OFF the switch element 114 at the time of the program operation. This enables the program of the reference data.

In addition, when the number of results of determination indicating the OFF state is larger than the number of results of determination indicating the ON state, the calibration circuit 113 updates the read level to a value larger than the current set value. When the number of results of determination indicating the OFF state is smaller than the number of results of determination indicating the ON state, the calibration circuit 113 updates the read level to a value smaller than the current set value.

In this way, the margin on the high voltage side of the voltage VLATCH and the margin on the low voltage side of the voltage VLATCH can be made equal, and thus, it is possible to improve the resistance to various variations.

In the above description, the read operation is performed implemented as a part of the read command processing. As a result, in the initial read command, the read level not calibrated is used.

After completion of the write operation, the control circuit 103 may start the read operation for the purpose of calibration of the read level even though the read command is not received. That is, after the write operation, the control circuit 103 may start the read operation without depending on the read command from the memory controller 20. The number of performances of the read operation without depending on the read command may be one or more.

With this configuration, after the read operation without depending on the read command, when the read command from the memory controller 20 is processed, it is possible to use the read level on which calibration has been performed.

In addition, in the description, the pair of second sense amplifier circuits 120-2 are provided for each read level. Only one pair of second sense amplifier circuits 120-2 corresponding to one read level may be provided. In this case, for example, when updating the read level corresponding to the pair of the second sense amplifier circuits 120-2, the calibration circuit 113 may estimate the amount of change of another read level based on the amount of change of the read level, and may update the other read level using the estimated amount of change. The amount of change of other read levels can be estimated using any method.

This configuration can make it unnecessary to provide a pair of second sense amplifier circuits 120-2 for each read level. As a result, the number of memory cells MT storing the reference data can be reduced, and it is possible to increase the number of memory cells MT storing the main data as much as the reduced amount.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a plurality of memory cells commonly connected to a word line and connected to a bit line, respectively, the plurality of memory cells including one or more pairs of reference memory cells that store reference data; and
a circuit peripheral to the memory cell array and configured to, during a read operation:
apply a read voltage to the word line;
for each pair of reference memory cells, cause sense nodes of bit lines connected to the reference memory cells to be electrically connected to each other;
determine whether each of the plurality of reference memory cells is in an ON state or an OFF state based on a voltage at a sense node of each of the plurality of bit lines; and
update the read voltage based on the number of reference memory cells determined to be in the ON state and the number of reference memory cells determined to be in the OFF state.

2. The semiconductor memory device according to claim 1, wherein
the circuit is further configured to:
during a program operation, apply a voltage to the word line to cause a threshold voltage of a first reference memory cell of a pair to be in a threshold voltage distribution adjacent to and less than the read voltage, and a threshold voltage of a second reference memory cell of the pair to be in a threshold voltage distribution adjacent to and greater than the read voltage, with respect to each of the one or more pairs of reference memory cells, and
after the program operation, carry out the read operation.

3. The semiconductor memory device according to claim 2, wherein
for each of the one or more pairs of reference memory cells, the sense nodes of the bit lines connected to reference memory cells of the pair is connected via a switch element, and
the circuit turns on the switch element for each of the one or more pairs of reference memory cells, during the read operation.

4. The semiconductor memory device according to claim 3, wherein the circuit turns off the switch element for each of the one or more pairs of reference memory cells, during the program operation.

5. The semiconductor memory device according to claim 2, wherein
the circuit is configured to carry out the program operation in response to a command, and then to carry out the read operation before receiving any other command.

6. The semiconductor memory device according to claim 2, wherein
the circuit is configured to carry out the program operation in response to a program command, and then to carry out the read operation in response to a read command received after the program command.

7. The semiconductor memory device according to claim 1, wherein
the circuit is configured to increase the read voltage in a case where the number of reference memory cells determined to be in the OFF state is greater than the number of reference memory cells determined to be in the ON state, and decrease the read voltage in a case where the number of reference memory cells determined to be in the ON state is greater than the number of reference memory cells determined to be in the OFF state.

8. The semiconductor memory device according to claim 1, wherein
the read voltage is one of a plurality of read voltages corresponding to a plurality of values of bits programmable in each of the plurality of memory cells, and
the circuit is further configured to, during the read operation:
apply a second read voltage among the plurality of read voltages to the word line, after applying the read voltage; and
update the second read voltage based on the number of reference memory cells determined to be in the ON state and the number of reference memory cells determined to be in the OFF state while the second read voltage is applied.

9. The semiconductor memory device according to claim 1, wherein the circuit is further configured to output, as read data, data of a value obtained based on a determination result of whether each of the memory cells that store user data is in the ON state or the OFF state, during the read operation.

10. The semiconductor memory device according to claim 1, wherein the memory cell array and the circuit are integrally provided on a same chip.

11. A memory system comprising:
a plurality of memory chips; and
a memory controller communicable to a host and configured to control the plurality of memory chips based on a request from the host, wherein
each of the plurality of memory chips comprising:
a memory cell array including a plurality of memory cells commonly connected to a word line and connected to a plurality of bit lines, respectively, the plurality of memory cells including one or more pairs of reference memory cells that store reference data; and
a circuit peripheral to the memory cell array and configured to, during a read operation:
apply a read voltage to the word line;
for each pair of reference memory cells, cause sense nodes of bit lines connected to the reference memory cells to be electrically connected to each other;
determine whether or not each of the plurality of reference memory cells is in an ON state or an OFF state based on a voltage at a sense node of each of the plurality of bit lines; and
update the read voltage based on the number of reference memory cells determined to be in the ON state and the number of reference memory cells determined to be in the OFF state.

12. A method of controlling a semiconductor memory device including a memory cell array including a plurality of memory cells commonly connected to a word line and connected to a bit line, respectively, the plurality of memory cells including one or more pairs of reference memory cells that store reference data, the method comprising, during a read operation:
applying a read voltage to the word line;
for each pair of reference memory cells, electrically connecting sense nodes of bit lines connected to the reference memory cells to each other;
determining whether each of the plurality of reference memory cells is in an ON state or an OFF state based on a voltage at a sense node of each of the plurality of bit lines; and
updating the read voltage based on the number of reference memory cells determined to be in the ON state and the number of reference memory cells determined to be in the OFF state.

13. The method of claim 12, further comprising:
during a program operation, applying a voltage to the word line to cause a threshold voltage of a first reference memory cell of a pair to be in a threshold voltage distribution adjacent to and less than the read voltage, and a threshold voltage of a second reference memory cell of the pair to be in a threshold voltage distribution adjacent to and greater than the read voltage, with respect to each of the one or more pairs of reference memory cells,
wherein the read operation is carried out after the program operation.

14. The method of claim 13, wherein
for each of the one or more pairs of reference memory cells, the sense nodes of the bit lines connected to reference memory cells of the pair is connected via a switch element, and
said electrically connecting sense nodes comprises turning on the switch element for each of the one or more pairs of reference memory cells.

15. The method of claim 14, further comprising:
during the program operation, turning off the switch element for each of the one or more pairs of reference memory cells.

16. The method of claim 13, wherein the program operation is carried out in response to a command, and then the read operation is carried out before receiving any other command.

17. The method of claim 13, wherein the program operation is carried out in response to a program command, and then the read operation is carried out in response to a read command received after the program command.

18. The method of claim 12, wherein said updating comprises:
increasing the read voltage in a case where the number of reference memory cells determined to be in the OFF state is greater than the number of reference memory cells determined to be in the ON state; and
decreasing the read voltage in a case where the number of reference memory cells determined to be in the ON state is greater than the number of reference memory cells determined to be in the OFF state.

19. The method of claim 12, wherein
the read voltage is one of a plurality of read voltages corresponding to a plurality of values of bits programmable in each of the plurality of memory cells that store user data, and
the method further comprising, during the read operation:
applying a second read voltage among the plurality of read voltages to the word line, after applying the read voltage; and
updating the second read voltage based on the number of reference memory cells determined to be in the ON state and the number of reference memory cells determined to be in the OFF state while the second read voltage is applied.

20. The method of claim 12, further comprising, during the read operation:
outputting, as read data, data of a value obtained based on a determination result of whether each of the memory cells that store data is in the ON state or the OFF state.
